(19) United States
(12) Patent Application Publication
(10) Pub. No.: US 2002/0114273 A1
(43) Pub. Date: Aug. 22, 2002

(54) Apparatus for data collection and analysis, method for the same, and recording medium

(75) Inventors: Makoto Tobita, Tokyo (JP); Shigeo Kawauchi, Tokyo (JP)

Correspondence Address: LOWE HAUPTMAN GOPSTEIN GILMAN & BERNER, LLP, Suite 310, 1700 Diagonal Road, Alexandria, VA, 22314, US

(73) Assignee: ADVANTEST CORPORATION

(21) Appl. No.: 09/788,427

(22) Filed: Feb. 21, 2001

(51) Int. Cl. G01R 31/08

(52) U.S. Cl. 370/229

(57) ABSTRACT

The invention provides a communication line analyzer provided with the filter processing function by the programming system that allows applying various filter conditions and handling sequential filter conditions.

The communication line analyzer receives a reception signal from a communication line, and extracts data through a specific filter condition. The analyzer contains a filter processing user-program with the language function that receives a data before filtering by a user's describing a program, sequentially executes the filter processing, and extracts an objective data after filtering to output. The analyzer also contains a memory in which the filter processing user-program is loaded, and further a sequential filter processor with an operational processing means that executes a specific filter processing to the data before filtering on the basis of the program loaded.

### BACKGROUND OF THE INVENTION

1. Field of Invention

The present invention relates to a communication line analyzer that analyzes signals running through the wireless or cable communication lines.

2. Description of the Related Art

The data or packet traffics have been increasing owing to the widespread Of the mobile communications and the Internet. Accompanied with the increased traffics, the throughput or the protocol throughput of communication controllers available on the market cannot match the purpose, whereby data or packets have been scrapped, which is going to be a serious system failure. Besides, failures in the protocols are estimated to become increasingly complicated accompanied with the popularization of communication services.

To investigate such failures or to confirm such traffics, the data collection/analysis apparatus (protocol analyzer, network analyzer, etc.) on the market is provided with multi-stage sequential filters or triggers that a user can set.

### SUMMARY OF INVENTION

However, restrictions on selection of the number of stages of the sequential filters and restrictions on selection of the triggers will increase the restrictions when a user investigates the failures or confirms the traffics.

Accordingly, the invention accepts it as a problem to provide a communication line analyzer that reduces the restrictions when a user investigates the failures or confirms the traffics.

According to the present invention described in claim 1, an apparatus for data collection and analysis includes: a data collection unit for acquiring data including packets, and a program execution unit for designating a data to be processed out of the data, and executing a program to perform a specific processing with respect to the designated data, wherein the program execution unit operates while the data collection unit acquires the data.

According to the data collection/analysis apparatus configured as the above, a user is able to reduce the restrictions on investigation of failures, or on confirmation of traffics by editing the programs arbitrarily.

According to the present invention described in claim 2, an apparatus for data collection and analysis as claimed in claim 1, further includes a data output unit that outputs the designated data out of the data acquired by the data collection unit to the program execution unit.

The present invention described in claim 3, is an apparatus for data collection and analysis as claimed in claim 1, wherein the program execution unit generates a log of the data.

The present invention described in claim 4, is an apparatus for data collection and analysis as claimed in claim 1, wherein the program execution unit displays an execution result.

According to the present invention described in claim 5, an apparatus for data collection and analysis as claimed in claim 1, further includes a display unit for displaying the data acquired by the data collection unit.

According to the present invention described in claim 6, a method for data collection and analysis includes: a data collection step for acquiring data including packets, and a program execution step for designating a data to be processed out of the data, and executing a program to perform a specific processing with respect to the designated data, wherein the program execution step operates while the data collection step acquires the data.

The present invention described in claim 7, is a computer-readable medium having a program of instructions for execution by the computer to perform a data collection and analysis processing, the data collection and analysis processing including: a data collection processing for acquiring data including packets, and a program execution processing for designating a data to be processed out of the data, and executing a program to perform a specific processing with respect to the designated data, wherein the program execution processing operates while the data collection processing acquires the data.

According to the present invention described in claim 8, an apparatus for data collection and analysis includes: a data collection device that acquires data including packets, and a program execution device that designates a data to be processed out of the data, and executes a program to perform a specific processing with respect to the designated data, wherein the program execution device operates while the data collection device acquires the data.

### BRIEF DESCRIPTION OF THE DRAWINGS

FIG. 1 is a block diagram of a communication line analyzer of the invention;

FIG. 2 is a chart illustrating an example of the filter-setting screen in case of the LAPD and the LAPB8/LAPB128;

FIG. 3 is a display example of a translation of a frame data;

FIG. 4 is a flow chart example illustrating a part of processing by the sequential filter processor of the invention;

FIG. 5 is another block diagram of the communication line analyzer of the invention; and

FIG. 6 is another block diagram of the communication line analyzer of the invention.

### DESCRIPTION OF THE PREFERRED EMBODIMENTS

One embodiment to which the invention is applied will be described with reference to the accompanying drawings. The contents of the descriptions hereunder do not limit the scope of the claims at all, and the components and the connections and the like that are described in the embodiment are not necessarily essential to the means to solve the problems.

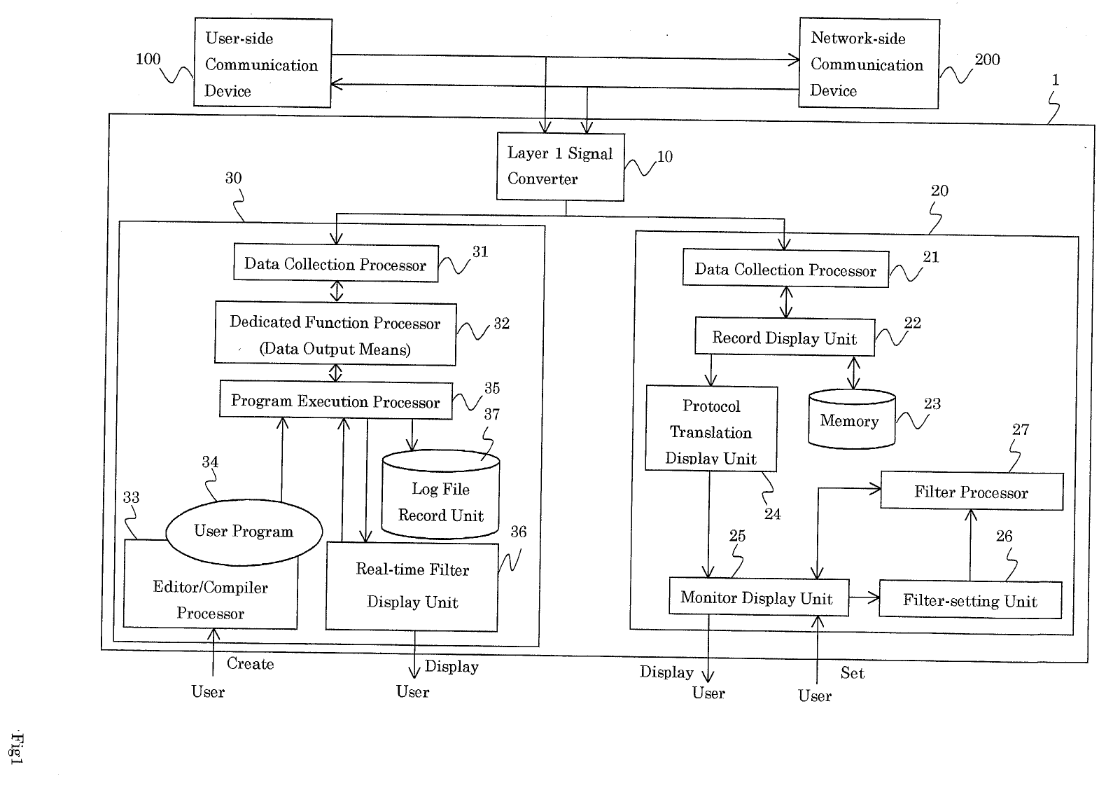

FIG. 1 is a block diagram illustrating the configuration of a data collection/analysis apparatus 1 relating to the embodiment of the invention. The data collection/analysis apparatus 1 fetches data communicated between a user-side communication device 100 and a network-side communication device 200, and analyzes the data. Here, the user-side communication device 100 signifies a fixed terminal, mobile terminal, client PC (personal computer), and the like. The network-side communication device 200 signifies a network terminal installation, base station, server, and the like. Further, for example, the communication line that couples the user-side communication device 100 and the network-side communication device 200 is composed of 2B+D-channel of the Basic Rate Interface, or 23B+D-channel of the Primary Rate Interface. In this embodiment, the data collection/analysis apparatus 1 is designed to fetch data through the communication line; however basically, it may fetch data being communicated. Therefore, the data collection/analysis apparatus 1 is applicable to a system in which a wireless communication is executed between the user-side communication device 100 and the network-side communication device 200.

FIG. 1 illustrates only one processing system; however generally, a parallel processing is carried out by a plurality of systems including the same components.

The data collection/analysis apparatus 1 includes a layer-1 signal converter 10, a monitor processor 20, and a real-time filter processor 30.

The layer 1 converter 10 selects a desired B-channel or D-channel out of the Basic Rate Interface or the Primary Rate Interface for the communication line. And, it receives communication data running through a selected channel. Also, on the basis of the specification of the layer 1, it acquires communication information of the communication frame while synchronizing the frame and other communication information, and outputs these information to the monitor processor 20 and the real-time filter processor 30.

The monitor processor 20 includes a data collection processor 21, a record display unit 22, a memory 23, a protocol translation display unit 24, a monitor display unit 25, a filter-setting unit 26, and a filter processor 27.

The data collection processor 21 receives the communication information that the layer 1 signal converter 10 outputs, generates the state transition data of the layer 1 and the like, and supplies the results to the record display unit 22. Further, the data collection processor 21 converts the communication information from the layer 1 signal converter 10 into the data of the layer N (N≧2, N: Natural Number), and supplies the results to the record display unit 22. In case of receiving the communication frame of the D-channel, the data collection processor 21 carries out the error detection based on the LAPD (Link Access Procedure on D-Channel), and outputs the results.

The record display unit 22 receives the data supplied from the data collection processor 21, and outputs a received data number indicating the sequence of the received data, a time stamp indicating the time when the data is received, and a group of data having other storage information applied thereto to the memory 23 and the protocol translation display unit 24.

The memory 23 receives a plurality of channels data outputted from the record display unit 22 to simultaneously store them. For example, the memory 23 simultaneously stores the data with regard to the B-channel and the data with regard to the D-channel. Here, the storage operation into the memory 23 is executed for a collection period designated by a user. That is, the memory 23 starts collection of the data from the communication line at the time of receiving the instruction to start measurement, and starts storage into a recording medium; and when it receives the instruction to stop collection from the user, the memory 23 stops the data collection after a designated collection period by a timer or the like, for example, after some ten seconds to some hours.

The protocol translation display unit 24 receives the data outputted from the record display unit 22, and supplies the monitor display unit 25 with display data after having executed the conversion or translation processing into a specific screen display configuration corresponding to the received data.

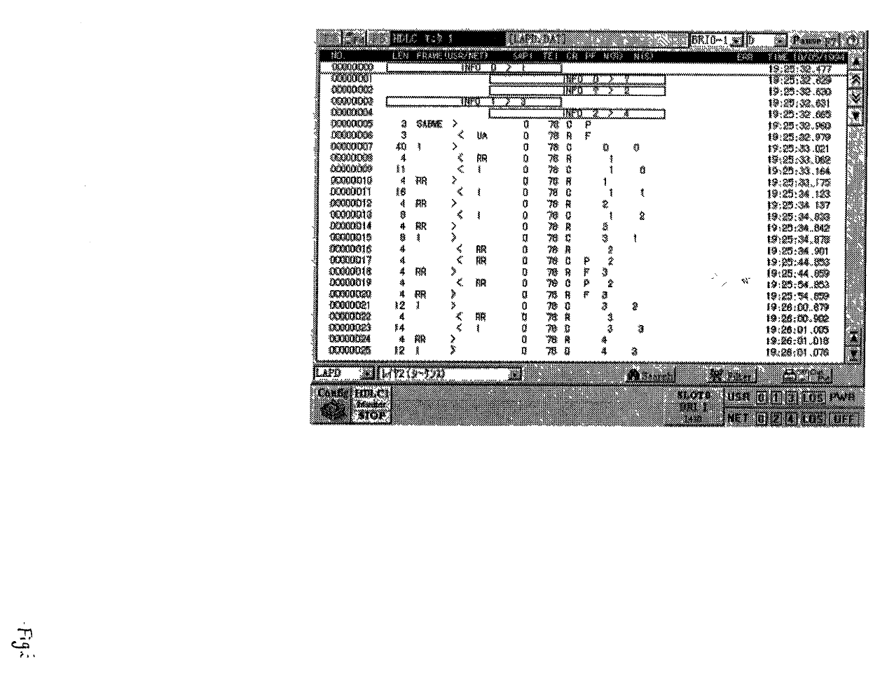

The monitor display unit 25 is provided with a display screen with a multi-window configuration, and receives the display data to present on the corresponding window with a specific display configuration. FIG. 3 illustrates a display example of the translation. In case of simultaneously displaying a plurality of channels, normally the monitor display unit 25 displays the channels on the individual windows.

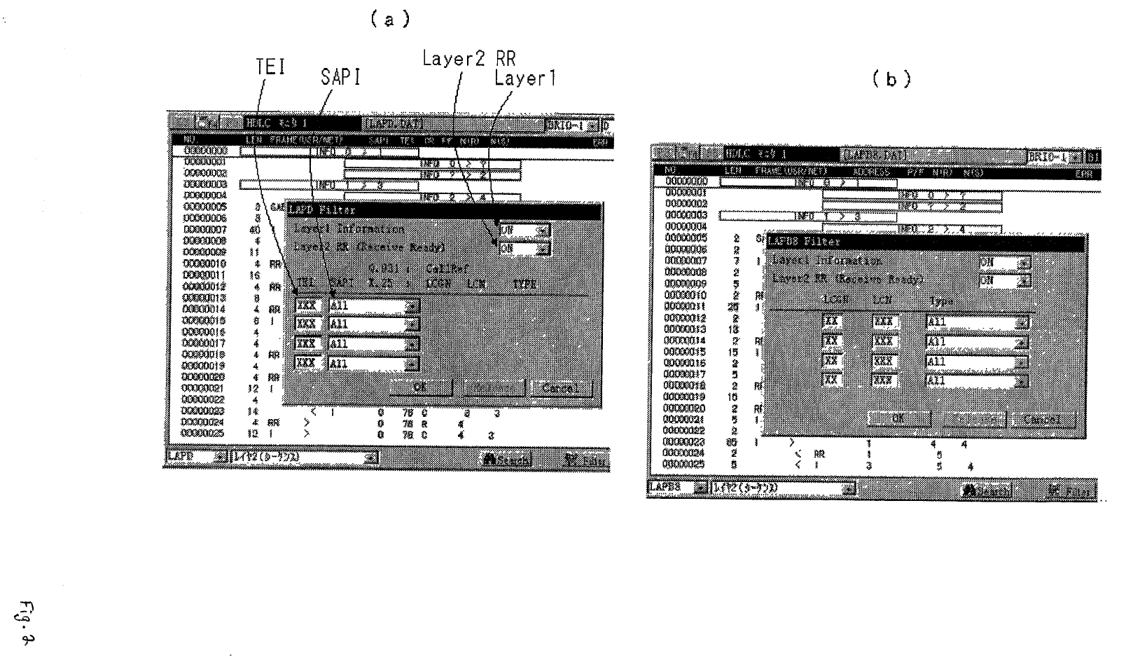

The filter-setting unit 26 is composed of a plurality of switches and registers that store various types of filter conditions, so that it can output the display data of a desired filter condition. The filter-setting unit 26 enables a user to alter the filter setting at any time on the menu screen of the monitor display unit 25, through a key input or the like. FIG. 2(a) illustrates an example when the inputted data conforms to the LAPD. The drawing illustrates the filter condition of four items, in which the first “Layer1 Information” signifies an ON/OFF switch with respect to whether or not the layer1 information is displayed. The second “Layer2 RR” signifies an ON/OFF switch with respect to whether or not the layer2 information is displayed. The third “TEI” signifies the Terminal Endpoint Identifier, which is provided with the registers for four channels that set the TEI values of 7 bits of the address bits. The fourth “SAPI” signifies the Service Access Point Identifier, which is provided with the registers for four channels that set the SAPI values of 6 bits indicating the type of the layer2. The filter-setting unit 26 supplies these filter conditions to the filter processor 27.

Depending on the inputted data, there appear different filter items, as seen in a filter condition corresponding to the previously written LAPD and a filter condition corresponding to the LAPB8/LAPB128 (see FIG. 2(b)). In any case, however, the filter condition is made up with the registers and switches in a semi-fixed configuration.

The filter processor 27 reads the display data once presented on the monitor display unit 25, and executes the filter processing on the basis of the filter condition from the filter-setting unit 26. That is, it compares to check whether the filter condition coincides with the corresponding data part or not; and if they are coincident, the filter processor 27 supplies the frame having the concerned data as the data after filtering to the monitor display unit 25. Further, it is possible to apply an identifying flag to the extracted data to store in a recording medium, so that the concerned extracted data can be used in a later occasion.

The real-time filter processor 30 possesses a data collection processor 31, a dedicated function processor (data output means) 32, an editor/compiler processor 33, a user program 34, a program execution processor 35, a real-time filter display unit 36, and a log file record unit 37.

The data collection processor 31 receives the communication information that the layer 1 signal converter 10 outputs, generates the state transition data of the layer 1 and the like, and supplies the results to the dedicated function processor (data output means) 32. Further, the data collection processor 31 converts the communication information from the layer 1 signal converter 10 into the data of the layer N (N≧2, N: Natural Number), and supplies the result to the dedicated function processor (data output means) 32. In case of receiving the communication frame of the D-channel, the data collection processor 31 carries out the error detection based on the LAPD (Link Access Procedure on D-Channel), and outputs the results.

The dedicated function processor (data output means) 32 receives the data from the data collection processor 31, and outputs the data designated by the user program 34 to the program execution processor 35.

The editor/compiler processor 33 is a means for programming a filter-processing program and compiling the program. The filter-processing program is compiled into an executive file, and the created executive file is loaded on the memory of the program execution processor 35. Here, the executive file that the compiler creates may be the machine language code, or the intermediate language code that accompanies the interpreter processing, if it can be handled by a CPU. Further, as for the filter value to be compared, a filter setting register, which is the same as the conventional, may be provided as desired, so that a user can program to alter the setting at any time through a key input or the like.

Although not illustrated in the drawing, to the user program 34 is applied the same language function as the simulation language which generates an arbitrary pseudo frame from this apparatus. The language function is provided with a general purpose processing function that is similar to the C language or BASIC language. In an example, there are variables, constants, arrays, random numbers, adding-subtracting multiplying dividing operators, relational operators, logical operators, bit operators, bit shift operators, IF statement, FOR statement, WHILE statement, CASE statement, data output functions, display functions, and so forth. Further, as a task function, the language function is provided with the EXTRACT function that reads a value at an arbitrary octet position in relation to the LAPD and LAPB, the RXFRLEN that examines a frame data length, and other functions dedicated to the frame processing.

The program execution processor 35 is an operation processing means that executes the user program 34, which includes a CPU and DSP, for example, and a memory in which the user program 34 is loaded. And, the program execution processor 35 loads the user program 34 on the memory in advance, and reads the program to carry out the filter processing. That is, the program execution processor 35 reads the data that the dedicated function processor (data output means) 32 outputs, checks a specified data of a frame on the basis of the user program 34, executes a specified branch processing, etc., on the basis of the checked result and performs the filter processing, specifies a frame to be outputted on the basis of the checked result, and supplies the real-time filter display unit 36 with the specified frame together with the frame before and after the concerned frame to be analyzed and displayed, as the data after filtering.

The real-time filter display unit 36 executes a data exchange to the program execution processor 35 by the input/output function, and displays in real time the filter processing result received from the program execution processor 35. That is, while the data collection/analysis apparatus 1 fetches communication data, the real-time filter display unit 36 displays the filter processing result.

The log file record unit 37 acquires data from the program execution processor 35, and records the data as a log file. For example, the log file record unit 37 records as a log file the contents of the user program 34 that the program execution processor 35 executed, and the functions that the program execution processor 35 used.

Next, the operation of the data collection/analysis apparatus 1 relating to the embodiment of the invention will be described.

First, the layer 1 signal converter 10 acquires communication data between the user-side communication device 100 and the network-side communication device 200. The layer 1 signal converter 10 acquires the communication information of the frame and the other communication information, and outputs the information to the monitor processor 20 and to the real-time filter processor 30.

The monitor processor 20 executes a monitor display processing, a data recording processing, and a filter processing of data after the monitor display.

The data collection processor 21 converts the communication information outputted by the layer 1 signal converter 10 into the state transition data of the layer 1 and the state transition data of the layer N (N≧2, N: Natural Number), and supplies the results to the record display unit 22. The record display unit 22 outputs a group of data such as a reception data number to the memory 23, and the memory 23 stores the data for a designated collection period. The record display unit 22 also outputs a group of data such as the reception data number to the protocol translation display unit 24. The protocol translation display unit 24 executes a conversion processing or a translation processing to the data into a specific screen display configuration, and the monitor display unit 25 displays the results. And, on the basis of the setting condition of the filter-setting unit 26, the filter processor 27 reads the display data once presented on the monitor display unit 25, and executes the filter processing based on the filter condition from the filter-setting unit 26. The filter processing result is displayed on the monitor display unit 25.

The real-time filter processor 30 executes a real-time monitor display processing as a major role.

The data collection processor 31 converts the communication information outputted by the layer 1 signal converter 10 into the state transition data of the layer 1 and the state transition data of the layer N (N≧2, N: Natural Number), and supplies the results to the dedicated function processor 32.

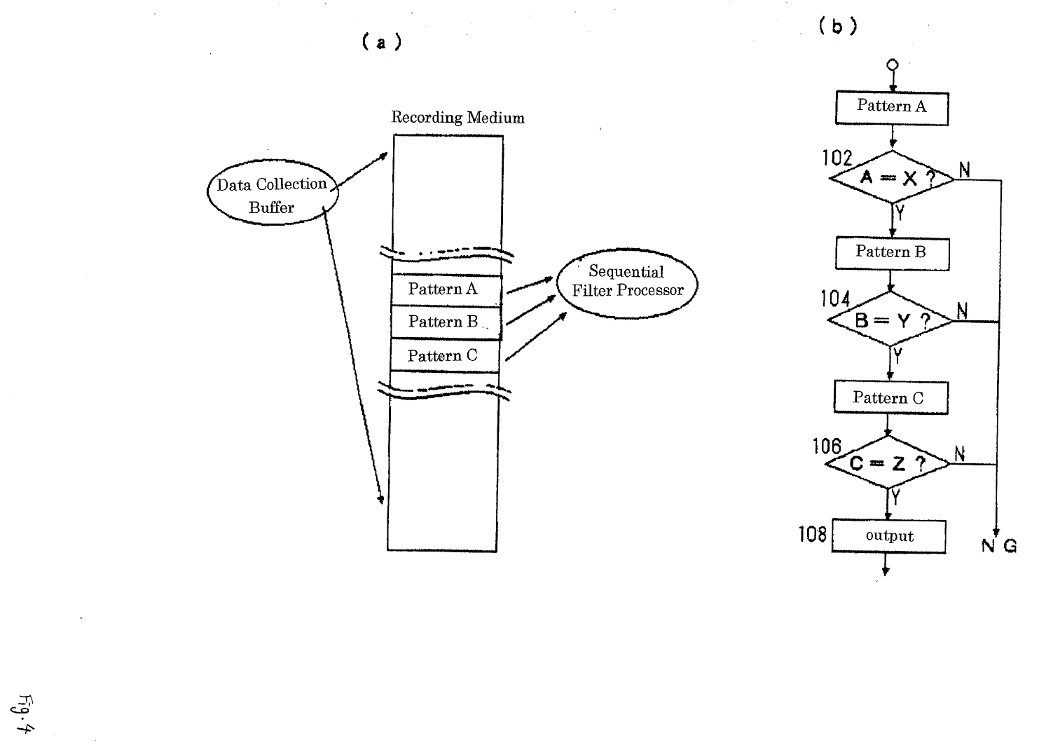

The dedicated function processor 32 outputs a designated data in the user program 34 to the program execution processor 35. The data that the dedicated function processor 32 outputs are assumed to be stored in the sequence of the patterns A, B, C as shown in FIG. 4(a), and the patterns are assumed to be a group of data that includes the frame information and the other time stamp information, and the like. And, the user program 34 created by the editor/compiler processor 33 is loaded in the program execution processor 35.

FIG. 4(b) illustrates an example of the filter processing by the program execution processor 35. This processing flow is a part of the whole filter processing that the program execution processor 35 executes. This part illustrates an example in which is executed a sequential filter that the program execution processor 35 outputs as the data after filtering including the concerned frame or a desired frame, when the first filter condition X is satisfied, next the second filter condition Y is satisfied, and thereafter the third filter condition Z is satisfied, whereby a multi-stage filter condition is satisfied.

The step 102 reads, in relation to the first filter condition X, the first pattern A of the patterns A, B, C that the dedicated function processor (data output means) 32 outputs, and compares the pattern A with the first filter condition X; and when the comparison results in coincidence, the step advances to the next, if otherwise, the step goes to the NG processing. Here, since the first filter condition X is configured with a programming system, complicated conditions as well as simple conditions can be designated to the first filter condition X. For example, singular or plural TEI and SAPI, 1-bit C/R (command/response), 2-bit EA (address field extension bit), and data content of a designated octet of the layer3 frame, and so forth can be written in the filter condition X. Since these are described using a user program for the filter processing, arbitrary combinations, data locations, bit lengths, number of words can arbitrarily be designated as the first filter condition.

The step 104 reads, in relation to the second filter condition Y, the next pattern B after the first condition X is satisfied, and compares the pattern B with the second filter condition Y; and if the comparison results in coincidence, the step goes to the next, otherwise, the step goes to the NG processing. Naturally, complicated filter conditions can arbitrarily be designated to the second filter condition Y as well.

The step 106 reads, in relation to the third filter condition Z, the next pattern C after the second condition Y is satisfied, and compares the pattern C with the third filter condition Z; and if the comparison results in coincidence, the step goes to the next, otherwise, the step goes to the NG processing. Naturally, complicated filter conditions can arbitrarily be designated to the third filter condition Z as well.

In the step 108, where the sequential filter conditions X, Y, Z are all satisfied, the concerned frame to be analyzed/displayed on the basis of the above condition, or some frames before and after the concerned frame, or a desired frame, or the like, is outputted as the data after filtering, to the real-time filter display unit 36.

Further, the log file record unit 37 records as a log file the contents of the user program 34 that the program execution processor 35 executed, and the functions that the program execution processor 35 used.

According to the above mentioned, the embodiment makes it possible to easily specify and output only the data having a complicated filter condition that the user designed, which is a significant advantage. Accordingly, it becomes possible to achieve the filter processing under various filter conditions such as: displaying data after specific times with regard to a desired filter condition, tracing a call connection sequence, setting the contents of data at a desired location of the layer2 or the layer3 as a filter condition, displaying the data when the sequential trigger condition is satisfied, and so forth.

Therefore, almost all the display contents on the display unit become noteworthy data, making it easy to recognize the data, which is advantageous. On the contrary, as in the conventional, great deals of useless displays are scrolled, and noteworthy displaying objects are run fast in a short time, thus overlooking them; however, the embodiment resolves such difficulties, and attains a significant improvement in terms of the user's visibility.

Further, the embodiment can also be applied to complicated sequential operations, and for example, it achieves an accurate easy capturing of a call connection sequence. Therefore, the embodiment achieves various filter functions with a high degree of freedom by way of the programming system, and thereby realizes a still more serviceable communication line analyzer.

The technological concept of this invention is not limited to the concrete configurations of the above embodiment. And, it can be applied to various modified examples as desired.

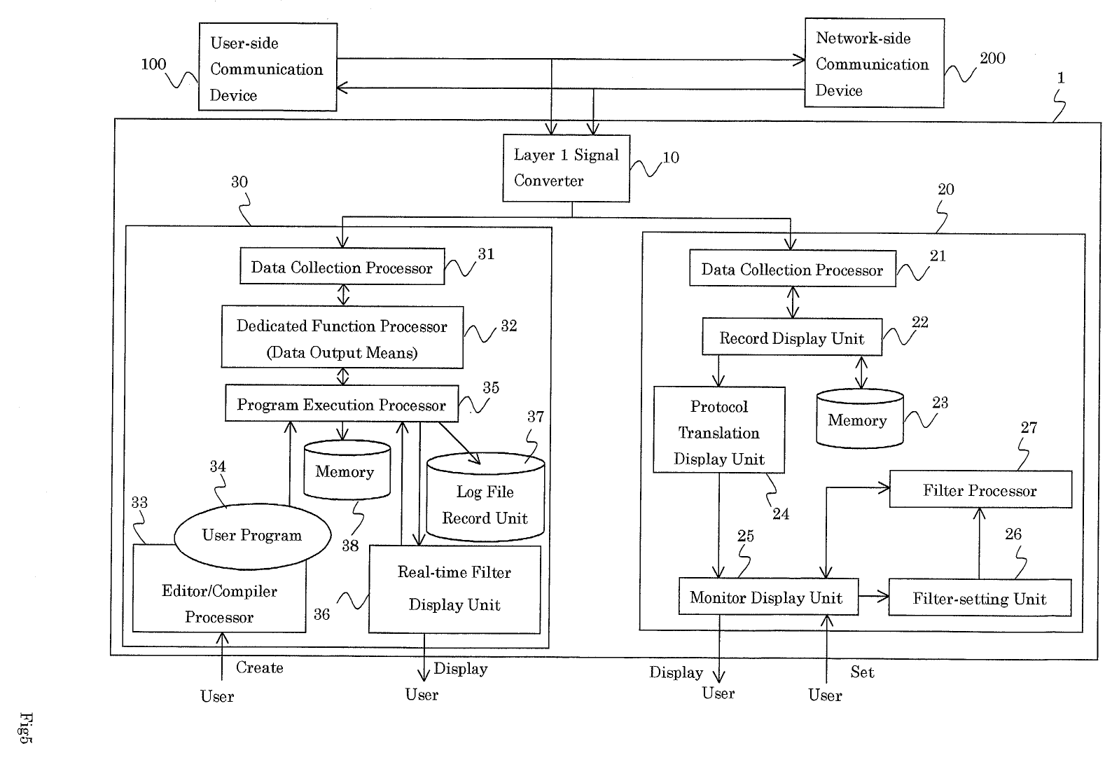

For example, as shown by the processing system diagram in FIG. 5, the configuration may be made such that the program execution processor 35 stores the data after filtering in a memory 38 and simultaneously supplies the data to the real-time filter display unit 36 as well. Here in this case, the program execution processor 35 needs to include such a high-speed controlling CPU and DSP as it can perform the processing in real time. Further, the data stored in the memory 38 needs to be supplied to the real-time filter display unit 36 to present on the display unit.

According to this configuration, firstly, useless data are not stored in the recording medium, which is advantageous, and as the result, the data quantity to be fetched and stored can significantly be reduced to 1/10-1/10000. As the result, this configuration is able to continuously collect data in the analysis of such an intermittent trouble as it can rarely occur less than once for more than several days.

And secondly, since the filtered result can be displayed in real time, a user need riot await the result for some ten seconds to some hours, as is usual with the conventional. The user is able to immediately analyze and/or judge the trouble by the evaluation of the display contents, and to spare such a useless waiting time and start a next analysis work.

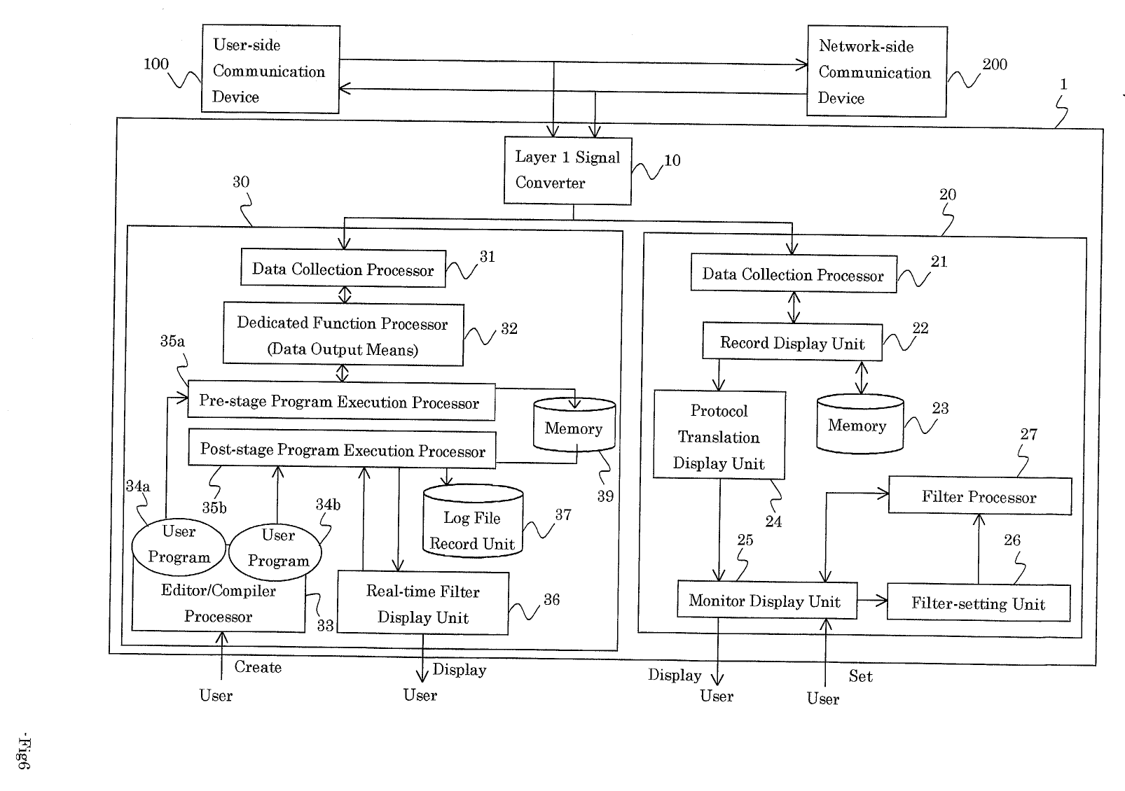

Further, as shown in FIG. 6, the configuration may be made such that the program execution processor 35 is divided into a pre-stage program execution processor 35a and a post-stage program execution processor 35b, and the corresponding user program 34 is divided into a pre-stage user program 34a and a post-stage user program 34b. Since the pre-stage program execution processor 35a is required to perform a real time processing, the pre-stage program execution processor 35a is placed in charge for such a comparably rough filter processing as it can process the reception data, and the filtered result is stored in a memory 39. As the result, the data quantity to be stored can significantly be reduced, compared to the conventional, and comparably low-speed elements such as serially executive controlling CPU and DSP can be applied to the filter processing, which is an advantage. The post-stage program execution processor 35b is placed in charge for such a minute filter processing as the above cannot handle. Such a dispersed filter configuration may be adopted to achieve the object. Further, the pre-stage program execution processor 35a may employ a semi-fixed filter condition system that executes a rough filter processing.

According to the data collection/analysis apparatus configured as above, the user is able to reduce the restrictions on the investigation of failures or on the confirmation of traffics, by arbitrarily editing the program.

What is claimed is:

1. An apparatus for data collection and analysis comprising:
a data collection means for acquiring data including packets, and
a program execution means for designating a data to be processed out of the data, and executing a program to perform a specific processing with respect to the designated data, wherein
the program execution means operates while the data collection means acquires the data.

2. An apparatus for data collection and analysis as claimed in claim 1, further comprising a data output means that outputs the designated data out of the data acquired by the data collection means to the program execution means.

3. An apparatus for data collection and analysis as claimed in claim 1, wherein the program execution means generates a log of the data.

4. An apparatus for data collection and analysis as claimed in claim 1, wherein the program execution means displays an execution result.

5. An apparatus for data collection and analysis as claimed in claim 1, further comprising a display means f or displaying the data acquired by the data collection means.

6. A method for data collection and analysis comprising:
a data collection step for acquiring data including packets, and
a program execution step for designating a data to be processed out of the data, and executing a program to perform a specific processing with respect to the designated data, wherein
the program execution step operates while the data collection step acquires the data.

7. A computer-readable medium having a program of instructions for execution by the computer to perform a data collection and analysis processing, said data collection and analysis processing comprising:
a data collection processing for acquiring data including packets, and
a program execution processing for designating a data to be processed out of the data, and executing a program to perform a specific processing with respect to the designated data, wherein
the program execution processing operates while the data collection processing acquires the data.

8. An apparatus for data collection and analysis comprising:
a data collection device that acquires data including packets, and
a program execution device that designates a data to be processed out of the data, and executes a program to perform a specific processing with respect to the designated data, wherein
the program execution device operates while the data collection device acquires the data.
